(19) United States
(12) Patent Application Publication
(10) Pub. No.: US 2025/0317120 A1
(43) Pub. Date: Oct. 9, 2025

(54) MULTILAYER PIEZOELECTRIC SUBSTRATE SURFACE ACOUSTIC WAVE DEVICE WITH POLYMER-BASED PACKAGING STRUCTURE

(71) Applicant: Skyworks Solutions, Inc., Irvine, CA (US)

(72) Inventor: Rei Goto, Osaka-Shi (JP)

(21) Appl. No.: 19/092,215

(22) Filed: Mar. 27, 2025

Related U.S. Application Data
(60) Provisional application No. 63/631,108, filed on Apr. 8, 2024.
(60) Provisional application No. 63/631,107, filed on Apr. 8, 2024.

(51) Int. Cl. H03H 9/25; H03H 3/08; H03H 9/02; H03H 9/64

(52) U.S. Cl. CPC H03H 9/25; H03H 3/08; H03H 9/02574; H03H 9/6483

(57) ABSTRACT

A packaged multi-layer piezoelectric substrate surface acoustic wave device is disclosed. The packaged acoustic wave device can include a multi-layer piezoelectric substrate including a piezoelectric layer and a sapphire substrate. The packaged acoustic wave device can include an interdigital transducer electrode in electrical communication with the piezoelectric layer. The packaged acoustic wave device can include a polymer-based packaging structure including a conductive structure, a sidewall, and a roof. The roof is at least partially positioned between the multi-layer piezoelectric substrate and a portion of the conductive structure. The sidewall is coupled to the multi-layer piezoelectric substrate. The interdigital transducer electrode is positioned between the sapphire substrate and the roof.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/631,108, filed Apr. 8, 2024, titled “PACKAGED MULTILAYER PIEZOELECTRIC SUBSTRATE SURFACE ACOUSTIC WAVE DEVICE,” and U.S. Provisional Patent Application No. 63/631,107, filed Apr. 8, 2024, titled “MULTILAYER PIEZOELECTRIC SUBSTRATE SURFACE ACOUSTIC WAVE DEVICE WITH POLYMER-BASED PACKAGING STRUCTURE,” are hereby incorporated by reference under 37 CFR 1.57 in their entirety.

### BACKGROUND

### Field

Embodiments of this disclosure relate to multilayer piezoelectric substrate surface acoustic wave (MPS-SAW) devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a packaged multi-layer piezoelectric substrate surface acoustic wave device including: a multi-layer piezoelectric substrate including a piezoelectric layer and a sapphire substrate; an interdigital transducer electrode in electrical communication with the piezoelectric layer; and a packaging structure including a polymer, the packaging structure coupled to the multi-layer piezoelectric substrate, the interdigital transducer electrode positioned between the sapphire substrate and the packaging structure.

In some embodiments, the techniques described herein relate to a packaged surface acoustic wave device wherein the multi-layer piezoelectric substrate further includes a silicon oxide layer between the piezoelectric layer and the sapphire substrate.

In some embodiments, the techniques described herein relate to a packaged surface acoustic wave device wherein the silicon oxide layer is in direct contact with the sapphire substrate.

In some embodiments, the techniques described herein relate to a packaged surface acoustic wave device wherein the packaging structure further includes a terminal.

In some embodiments, the techniques described herein relate to a packaged surface acoustic wave device wherein the packaging structure further includes a conductive structure electrically connecting the terminal and the multi-layer piezoelectric substrate.

In some embodiments, the techniques described herein relate to a packaged surface acoustic wave device wherein the conductive structure includes a metal trace.

In some embodiments, the techniques described herein relate to a packaged surface acoustic wave device wherein the conductive structure includes a patterned metal plate.

In some embodiments, the techniques described herein relate to a packaged surface acoustic wave device wherein the packaging structure includes a sidewall and a roof, the sidewall extends between the multi-layer piezoelectric substrate and the roof.

In some embodiments, the techniques described herein relate to a packaged surface acoustic wave device wherein the roof includes a first roof portion and a second roof portion having different materials.

In some embodiments, the techniques described herein relate to a packaged surface acoustic wave device wherein the packaging structure has a coefficient of thermal expansion greater than 0 ppm/° C. and equal to or less than 35 ppm/° C.

In some aspects, the techniques described herein relate to a method of forming a packaged multi-layer piezoelectric substrate surface acoustic wave device, the method including: providing a multi-layer piezoelectric substrate and an interdigital transducer electrode, the multi-layer piezoelectric substrate having a piezoelectric layer and a sapphire substrate, the interdigital transducer electrode in electrical communication with the piezoelectric layer; and coupling a packaging structure to the multi-layer piezoelectric substrate such that the interdigital transducer electrode is positioned between the sapphire substrate and the packaging structure, the packaging structure including a polymer.

In some embodiments, the techniques described herein relate to a method wherein the multi-layer piezoelectric substrate further includes a silicon oxide layer between the piezoelectric layer and the sapphire substrate.

In some embodiments, the techniques described herein relate to a method wherein the silicon oxide layer is in direct contact with the sapphire substrate.

In some embodiments, the techniques described herein relate to a method wherein the packaging structure further includes a terminal.

In some embodiments, the techniques described herein relate to a method wherein the packaging structure further includes a conductive structure electrically connecting the terminal and the multi-layer piezoelectric substrate.

In some embodiments, the techniques described herein relate to a method wherein the conductive structure includes a metal trace.

In some embodiments, the techniques described herein relate to a method wherein the conductive structure includes a patterned metal plate.

In some embodiments, the techniques described herein relate to a method wherein the packaging structure includes a sidewall and a roof, the sidewall extends between the multi-layer piezoelectric substrate and the roof.

In some embodiments, the techniques described herein relate to a method wherein the roof, the sidewall and the multi-layer piezoelectric substrate together define a cavity in which the interdigital transducer electrode is positioned.

In some embodiments, the techniques described herein relate to a method wherein the packaging structure has a coefficient of thermal expansion greater than 0 ppm/° C. and equal to or less than 35 ppm/° C.

In some aspects, the techniques described herein relate to a packaged multi-layer piezoelectric substrate surface acoustic wave device including: a multi-layer piezoelectric substrate surface acoustic wave device including a multi-layer piezoelectric substrate having a piezoelectric layer and a sapphire substrate, and an interdigital transducer electrode in electrical communication with the piezoelectric layer; and a packaging structure coupled to the multi-layer piezoelectric substrate, the interdigital transducer electrode positioned between the sapphire substrate and the packaging structure, a difference between a coefficient of thermal expansion of the multi-layer piezoelectric substrate surface acoustic wave device and a coefficient of thermal expansion of the packaging structure being less than 35 ppm/° C.

In some aspects, the techniques described herein relate to a packaged multi-layer piezoelectric substrate surface acoustic wave device including: a multi-layer piezoelectric substrate including a piezoelectric layer and a sapphire substrate; an interdigital transducer electrode in electrical communication with the piezoelectric layer; and a polymer-based packaging structure including a conductive structure, a sidewall, and a roof, the roof at least partially positioned between the multi-layer piezoelectric substrate and a portion of the conductive structure, the sidewall coupled to the multi-layer piezoelectric substrate, and the interdigital transducer electrode positioned between the sapphire substrate and the roof.

In some embodiments, the techniques described herein relate to a packaged surface acoustic wave device wherein the roof includes a first roof portion between the multi-layer piezoelectric substrate and the portion of the conductive structure, and a second roof portion.

In some embodiments, the techniques described herein relate to a packaged surface acoustic wave device wherein the second roof portion includes a silica-filled polymer.

In some embodiments, the techniques described herein relate to a packaged surface acoustic wave device wherein the portion of the conductive structure is positioned between the first and second roof portions.

In some embodiments, the techniques described herein relate to a packaged surface acoustic wave device wherein the multi-layer piezoelectric substrate further includes a silicon oxide layer between the piezoelectric layer and the sapphire substrate.

In some embodiments, the techniques described herein relate to a packaged surface acoustic wave device wherein the silicon oxide layer is in direct contact with the sapphire substrate.

In some embodiments, the techniques described herein relate to a packaged surface acoustic wave device wherein the polymer-based packaging structure further includes a terminal, and the conductive structure connects the terminal and the multi-layer piezoelectric substrate.

In some embodiments, the techniques described herein relate to a packaged surface acoustic wave device wherein the conductive structure includes a metal trace.

In some embodiments, the techniques described herein relate to a packaged surface acoustic wave device wherein the conductive structure includes a patterned metal plate.

In some embodiments, the techniques described herein relate to a packaged surface acoustic wave device wherein the roof, the sidewall and the multi-layer piezoelectric substrate together define a cavity in which the interdigital transducer electrode is positioned.

In some embodiments, the techniques described herein relate to a packaged surface acoustic wave device wherein the polymer-based packaging structure has a coefficient of thermal expansion greater than 0 ppm/° C. and equal to or less than 35 ppm/° C.

In some aspects, the techniques described herein relate to a method of forming a packaged multi-layer piezoelectric substrate surface acoustic wave device, the method including: providing a multi-layer piezoelectric substrate device including a sapphire substrate, a piezoelectric layer over the sapphire substrate, and an interdigital transducer electrode in electrical communication with the piezoelectric layer; and coupling a polymer-based packaging structure to the multi-layer piezoelectric substrate device, the polymer-based packaging structure including a conductive structure, a sidewall, and a roof, the roof at least partially positioned between the multi-layer piezoelectric substrate and a portion of the conductive structure, and the interdigital transducer electrode positioned between the sapphire substrate and the roof.

In some embodiments, the techniques described herein relate to a method wherein coupling the polymer-based packaging structure includes coupling the sidewall to the multi-layer piezoelectric substrate.

In some embodiments, the techniques described herein relate to a method wherein the roof includes a first roof portion between the multi-layer piezoelectric substrate and the portion of the conductive structure, and a second roof portion including a silica-filled polymer.

In some embodiments, the techniques described herein relate to a method wherein the portion of the conductive structure is positioned between the first and second roof portions.

In some embodiments, the techniques described herein relate to a method wherein multi-layer piezoelectric substrate further includes a silicon oxide layer between the piezoelectric layer and the sapphire substrate.

In some embodiments, the techniques described herein relate to a method wherein the polymer-based packaging structure further includes a terminal, and the conductive structure connects the terminal and the multi-layer piezoelectric substrate.

In some embodiments, the techniques described herein relate to a method wherein the conductive structure includes a metal trace or a patterned metal plate.

In some embodiments, the techniques described herein relate to a method wherein the roof, the sidewall and the multi-layer piezoelectric substrate together define a cavity in which the interdigital transducer electrode is positioned.

In some embodiments, the techniques described herein relate to a method wherein the polymer-based packaging structure has a coefficient of thermal expansion greater than 0 ppm/° C. and equal to or less than 35 ppm/° C.

In some aspects, the techniques described herein relate to a packaged multi-layer piezoelectric substrate surface acoustic wave device including: a multi-layer piezoelectric substrate surface acoustic wave device including a multi-layer piezoelectric substrate having a piezoelectric layer and a sapphire substrate, and an interdigital transducer electrode in electrical communication with the piezoelectric layer; and a polymer-based packaging structure including a conductive structure, a sidewall, and a roof, the roof having a first roof portion and a second roof portion, the conductive structure positioned between the first roof portion and the second roof portion, and the interdigital transducer electrode positioned between the sapphire substrate and the roof.

The present disclosure relates to U.S. Patent Application No. ______ [Attorney Docket SKYWRKS. 1531A1], titled “PACKAGED MULTILAYER PIEZOELECTRIC SUBSTRATE SURFACE ACOUSTIC WAVE DEVICE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 is a schematic cross sectional side view of a packaged multilayer piezoelectric substrate (MPS) surface acoustic wave (SAW) device according to an embodiment.

FIG. 2 is a schematic cross sectional side view of a packaged MPS-SAW device according to an embodiment.

FIG. 3 is a schematic cross sectional side view of a packaged MPS-SAW device according to an embodiment.

FIG. 4A is a simulated cross-sectional side view of a packaged temperature compensated surface acoustic wave (TC-SAW) device after a temperature cycle.

FIG. 4B is a graph showing a vertical displacement in the y-axis and a lateral location in the x-axis of the packaged TC-SAW device of FIG. 4A.

FIG. 5A is a simulated cross-sectional side view of a packaged MPS-SAW device after a temperature cycle.

FIG. 5B is a graph showing a vertical displacement in the y-axis and a lateral location in the x-axis of the packaged MPS-SAW device of FIG. 5A.

FIG. 6A is a simulated cross-sectional side view of a packaged MPS-SAW device of FIG. 2 after a temperature cycle.

FIG. 6B is a graph showing a vertical displacement in the y-axis and a lateral location in the x-axis of the packaged MPS-SAW device of FIG. 6A.

FIG. 7A is a simulated cross-sectional side view of a packaged MPS-SAW device of FIG. 3 after a temperature cycle.

FIG. 7B is a graph showing a vertical displacement in the y-axis and a lateral location in the x-axis of the packaged MPS-SAW device of FIG. 7A.

FIG. 8A is a simulated cross-sectional side view of a packaged MPS-SAW device after a temperature cycle.

FIG. 8B is a graph showing a vertical displacement in the y-axis and a lateral location in the x-axis of the packaged MPS-SAW device of FIG. 8A.

FIG. 9 is a graph showing comparison between the electrical performances of an MPS-SAW device with a silicon substrate and an MPS-SAW device with a sapphire substrate.

FIG. 10A is a schematic diagram of a transmit filter that includes a surface acoustic wave resonator according to an embodiment.

FIG. 10B is a schematic diagram of a receive filter that includes a surface acoustic wave resonator according to an embodiment.

FIG. 11 is a schematic diagram of a radio frequency module that includes a surface acoustic wave resonator according to an embodiment.

FIG. 12 is a schematic diagram of a radio frequency module that includes filters with surface acoustic wave resonators according to an embodiment.

FIG. 13 is a schematic block diagram of a module that includes an antenna switch and duplexers that include a surface acoustic wave resonator according to an embodiment.

FIG. 14A is a schematic block diagram of a module that includes a power amplifier, a radio frequency switch, and duplexers that include a surface acoustic wave resonator according to an embodiment.

FIG. 14B is a schematic block diagram of a module that includes filters, a radio frequency switch, and a low noise amplifier according to an embodiment.

FIG. 15A is a schematic block diagram of a wireless communication device that includes a filter with a surface acoustic wave resonator in accordance with one or more embodiments.

FIG. 15B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate (MPS) SAW device.

A multilayer piezoelectric substrate (MPS) surface acoustic wave (SAW) device can include a support substrate, a piezoelectric layer over the support substrate, and an interdigital transducer (IDT) electrode in electrical communication with the piezoelectric layer. The thermal dissipation ability of the MPS-SAW device is generally greater than other types of SAW devices, such as a temperature compensated (TC) SAW device that includes a temperature compensation layer over the IDT electrode.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, high power durability can be a significant aspect for enabling reliable SAW devices. Further, high temperature cycle reliability can be a significant aspect for enabling mass production of SAW devices.

A SAW device can be packaged as a packaged SAW device. The packaged SAW device includes the SAW device and a packaging structure coupled to the SAW device. A coefficient of thermal expansion mismatch between the SAW device and the packaging structure can cause mechanical distortion, which can lead to temperature cycle test failures. In TC-SAW devices, typically, the piezoelectric layer (e.g., a lithium niobate layer or a lithium tantalate layer) can have a relatively high coefficient of thermal expansion and a relatively low Young's modulus, and the TC-SAW devices may have a high temperature cycle reliability. However, as compared to MPS-SAW devices the TC-SAW devices typically have lower device performance. A packaging structure that includes a relatively low coefficient of thermal expansion material (e.g., silicon) can be used to reduce a coefficient of thermal expansion mismatch between the substrate of the MPS-SAW devices. However, a silicon packaging structure can cause direct current (DC) leakage in some applications, which can degrade the device performance. The DC leakage can be electrical current leakage through, for example, a substrate of the SAW device.

Various embodiments disclosed herein relate to packaged multilayer piezoelectric substrate (MPS) surface acoustic wave (SAW) devices that enable improved temperature cycle reliability and reduced DC leakage. A packaged MPS-SAW device according to some embodiments includes an MPS-SAW device and a packaging structure coupled to the SAW device. The MPS-SAW device includes a support substrate, a piezoelectric layer, and an interdigital transducer electrode in electrical communication with the piezoelectric layer. The support substrate can be a sapphire substrate. The packaging structure can include a dielectric material, such as a polymer, and a conductive routing structure. In some embodiments, the packaging structure can also include a material (e.g., silicon) with a lower coefficient of thermal expansion than the polymer. The packaging structure disclosed herein can be referred to as a polymer-based packaging structure. The SAW device and the packaging structure can be coupled such that the interdigital transducer electrode is positioned between the support substrate and the packaging structure. The sapphire substrate can provide a packaged MPS-SAW device that has a relatively low mechanical stress and low or no parasitic surface conductance.

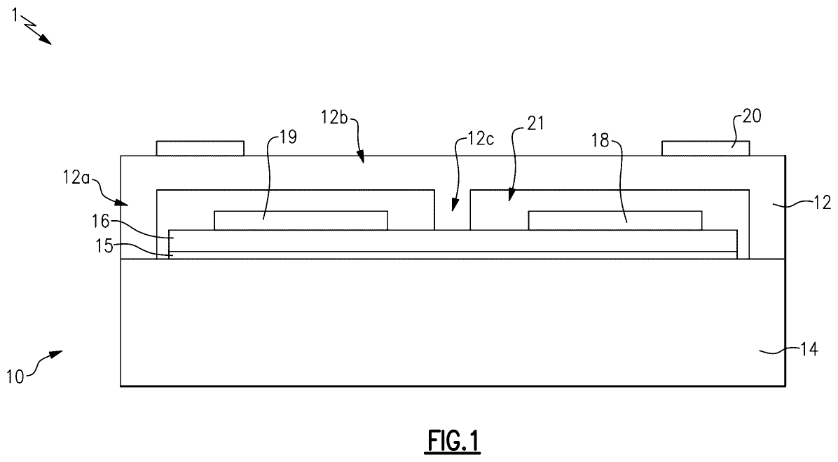

FIG. 1 is a schematic cross-sectional side view of a packaged multilayer piezoelectric substrate (MPS) surface acoustic wave (SAW) device 1 according to an embodiment. The packaged MPS-SAW device 1 can include an MPS-SAW device 10 and a packaging structure 12. The MPS-SAW device 10 can include a support substrate 14, a functional layer 15 over the support substrate 14, a piezoelectric layer 16 over the functional layer 15, and an interdigital transducer electrode 18. The interdigital transducer electrode 18 can be in electrical communication with the piezoelectric layer 16. The support substrate 14, the functional layer 15, and the piezoelectric layer 16 can together define an MPS. The packaging structure 12 can include a sidewall 12a, a roof 12b, and a pillar 12c. In some embodiments, the MPS-SAW device 10 can include a plurality of interdigital transducer electrodes including, for example, the interdigital transducer electrode 18 and an interdigital transducer electrode 19.

The support substrate 14 can have a relatively high acoustic impedance. For example, the support substrate 14 can have a higher impedance than an impedance of the piezoelectric layer 16 and a higher thermal conductivity than a thermal conductivity of the piezoelectric layer 16. The support substrate 14 can include a dielectric material. For example, the support substrate 14 can include sapphire or aluminum oxide (Al₂O₃). As compared to some other materials, such as silicon, sapphire has lower or no parasitic surface conductance as sapphire is dielectric. The multilayer piezoelectric substrate (MPS) that includes a sapphire support substrate can be referred to as a sapphire MPS.

The illustrated MPS-SAW device 10 includes the functional layer 15 between the piezoelectric layer 16 and the support substrate 14. The functional layer 15 can be, for example, a single crystal layer. In some embodiments, the functional layer 15 can be a silicon oxide layer (e.g., a silicon dioxide (SiO₂)) layer. In some embodiment, the functional layer 15 can function as an adhesion layer. In some embodiments, a thickness of the functional layer 15 can be the same as, generally similar to, or thinner than the thickness of the piezoelectric layer 16.

The piezoelectric layer 16 can include any suitable piezoelectric layer, such as a lithium based piezoelectric layer. In some embodiments, the piezoelectric layer 16 can be a lithium tantalate (LT) layer. For example, the piezoelectric layer 16 can be an LT layer having a cut angle of 20° (20° Y-cut X-propagation LT) or a cut angle of 60° (60° Y-cut X-propagation LT). For example, the piezoelectric layer 16 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 16. For example, the piezoelectric layer 16 can be an LN layer having a cut angle of about 118° (118° Y-cut X-propagation LN) or more or a cut angle of about 132° (132 Y-cut X-propagation LN) or less. For example, the piezoelectric layer 16 can be 125±20° Y-cut LN, 125±15° Y-cut LN, 125±10° Y-cut LN, or 125±5° Y-cut LN. A thickness of the piezoelectric layer 16 can be selected based on a wavelength 2 or L of a surface acoustic wave generated by the MPS-SAW device 10 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 16 can be sufficiently thick to avoid significant frequency variation. For example, the thickness of the piezoelectric layer 16 can be in a range of 0.1 L to 0.5, 0.1 L to 0.3 L, or 0.1 L to 0.2 L. Selecting the thickness of the piezoelectric layer 16 from these ranges can be critical in avoiding significant frequency variation and providing sufficient temperature coefficient of frequency for the MPS-SAW device 10. In some embodiments, the piezoelectric layer 16 can include lithium tantalate (LT) and lithium niobate (LN).

The IDT electrode 18 can include any suitable IDT electrode material. For example, the IDT electrode 18 can include molybdenum (Mo), aluminum (Al), copper (Cu), Magnesium (Mg), titanium (Ti), tungsten (W), the like, or any suitable combination thereof. The IDT electrode 18 can have a multilayer structure that includes a first layer and a second layer. One of the first layer and the second layer can be more electrically conductive than the other, and the other one can be more durable (e.g., resistive to metal fatigue). In some embodiments, the first layer or the second layer can have a higher mass density and/or higher Young's modulus than the other. In some embodiments, the IDT electrode 19 can have the same or generally similar structural characteristics as the IDT electrode 18. The interdigital transducer electrode 18 can be formed with (e.g., formed on or at least partially in) the piezoelectric layer 16. The piezoelectric layer 16 and the IDT electrode 18, 19 can be provided in any suitable manner. For example, the piezoelectric layer 16 and the IDT electrode 18, 19 can be provided in sequence. When the interdigital transducer electrode 18, 19 is provided at least partially in the piezoelectric layer 16, the piezoelectric layer 16 can be partially etched and/or provided in a plurality of steps.

The packaging structure 12 can be coupled to the MPS-SAW device 10. In some embodiments, the packaging structure 12 can be coupled to the support substrate 14 and/or the piezoelectric layer 16 of the MPS-SAW device 10. For example, the sidewall 12a can be coupled to the support substrate 14 and the pillar 12c can be coupled to the piezoelectric layer 16. In some embodiments, the sidewall 12a can be in contact with the support substrate 14 as shown, or in contact with the functional layer 15 and/or the piezoelectric layer 16. In some other embodiments, an adhesion layer may be provided between the sidewall 12a and the MPS-SAW device 10. The interdigital transducer electrode 18 can be positioned between the support substrate 14 and the roof 12b of the packaging structure 12. For example, the IDT electrodes 18, 19 can be positioned in a cavity 21 formed at least in part by the sidewall 12a, the roof 12b, and the MPS. The pillar 12c can be positioned in the cavity 21. The pillar 12c can be positioned laterally between the IDT electrode 18 and the IDT electrode 19.

The packaging structure 12 can also include a terminal 20 for connecting the packaged MPS-SAW device 1 to an external system or substrate (not show). The packaging structure 12 can include an electrical routing (not show) between the MPS-SAW device 10 and the terminal 20. The electrical routing can include a conductive trace, a conductive line, a conductive plate, and/or a conductive via.

The packaging structure 12 can include a polymer. For example, the packaging structure 12 can include 10% or more, 25% or more, 50% or more, 75% or more in volume of the polymer. An overall coefficient of thermal expansion (CTE) of the packaging structure 12 can be in a range between 35 ppm/° C. and 70 ppm/° C., 35 ppm/° C. and 65 ppm/° C., or 50 ppm/° C. and 70 ppm/° C. In some embodiments, the polymer can include silica-based filler. In some embodiments, a difference between the CTE of the MPS-SAW device 10 and the CTE of the packaging structure 12 can be in a range between 0 ppm/° C. and 35 ppm/° C., 5 ppm/° C. and 35 ppm/° C., 5 ppm/° C. and 20 ppm/° C., or 10 ppm/° C. and 30 ppm/° C.

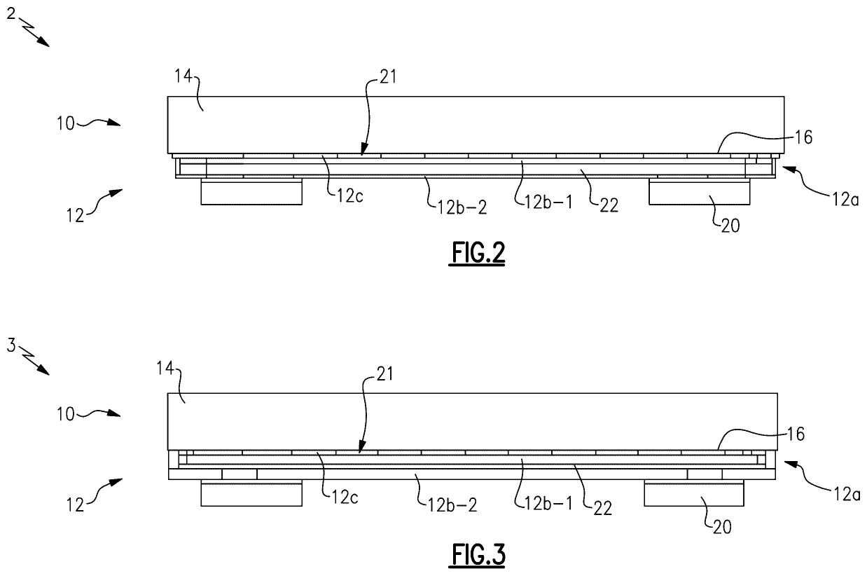

FIG. 2 is a schematic cross-sectional side view of a packaged multilayer piezoelectric substrate (MPS) surface acoustic wave (SAW) device 2 according to an embodiment. Unless otherwise noted, the components of the packaged MPS-SAW device 2 shown in FIG. 2 may be structurally and/or functionally the same as or generally similar to like components disclosed herein. The packaged MPS-SAW device 2 can include an MPS-SAW device 10 and a packaging structure 12. The MPS-SAW device 10 can include a support substrate 14, a piezoelectric layer 16, and one or more interdigital transducer (IDT) electrodes (not shown). The IDT electrodes can be positioned in a cavity 21 formed at least in part by the sidewall 12a, the first roof portion 12b-1, the second roof portion 12b-2, and the MPS.

The packaging structure 12 can include a sidewall 12a, a first roof portion 12b-1, a second roof portion 12b-2, a pillar 12c, a terminal 20, and a conductive structure 22. At least a portion of the conductive structure 22 can be positioned between the first and second roof portions 12b-1, 12b-2. The conductive structure 22 can include a conductive trace, a conductive line, a conductive plate, and/or a conductive via, and be configured to provide electrical routing between the MPS-SAW device 10 and the terminal 20. The conductive structure 22 can include any suitable material, such as copper or aluminum. In some embodiments, the conductive structure 22 can be patterned. The terminal 20 can include solder. The sidewall 12a, the first roof portion 12b-1, the second roof portion 12b-2, and the pillar 12c can include a polymer.

FIG. 3 is a schematic cross sectional side view of a packaged multilayer piezoelectric substrate (MPS) surface acoustic wave (SAW) device 3 according to an embodiment. Unless otherwise noted, the components of the packaged MPS-SAW device 3 shown in FIG. 3 may be structurally and/or functionally the same as or generally similar to like components disclosed herein. The packaged MPS-SAW device 3 can be generally similar to the packaged MPS-SAW device 2 of FIG. 2 except that the second roof portion 12b-2 in the packaged MPS-SAW device 3 is a silicon composite or silica-filled polymer. The silica-filled polymer can have a coefficient of thermal expansion greater than 0 ppm/° C. and equal to or less than 35 ppm/° C.

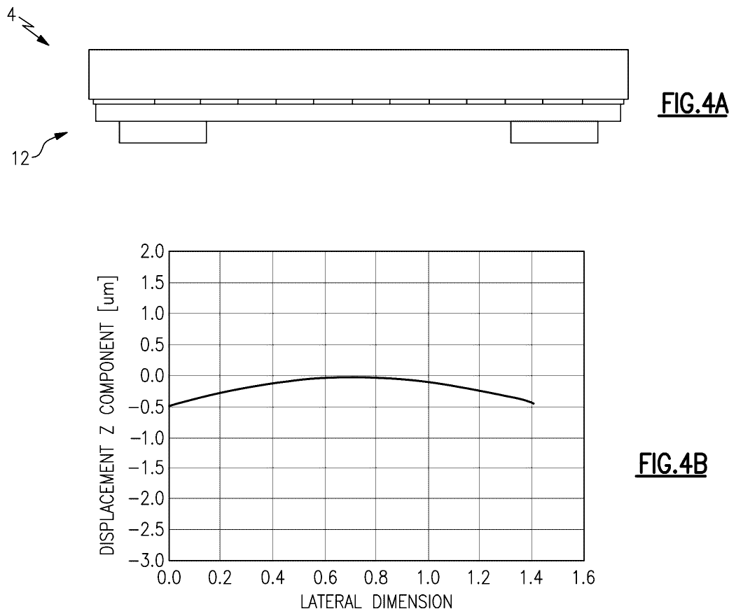

The packaged MPS-SAW devices disclosed herein that include a combination of a sapphire MPS and a polymer-based packaging structure can enable improved temperature cycle reliability and reduced DC leakage. In some applications, a displacement caused by the device deformation due to a coefficient of thermal expansion mismatch over 2μμm is considered significantly large and unreliable. In some applications, the displacement of 2 μm or less, 1.5 μm or less, 1.2 μm or less, 1 μm or less, or 0.5 μm or less are considered sufficiently small and reliable. FIGS. 4A-8B show results of temperature cycle tests conducted for five different packaged SAW devices.

FIG. 4A is a simulated cross-sectional side view of a packaged temperature compensated surface acoustic wave (TC-SAW) device 4 after a temperature cycle. FIG. 4B is a graph showing a vertical displacement in the y-axis and a lateral location in the x-axis of the packaged TC-SAW device 4 of FIG. 4A. The packaged TC-SAW device 4 includes a TC-SAW device that includes a lithium niobate piezoelectric layer and the packaging structure 12 shown in FIG. 2. The simulation results of FIGS. 4A and 4B indicate that the packaged TC-SAW device 4 has a sufficiently small (about 0.5 μm) vertical displacement after the temperature cycle. Also, the simulation results of FIGS. 4A and 4B indicate that the DC leakage was sufficiently blocked in the packaged TC-SAW device 4.

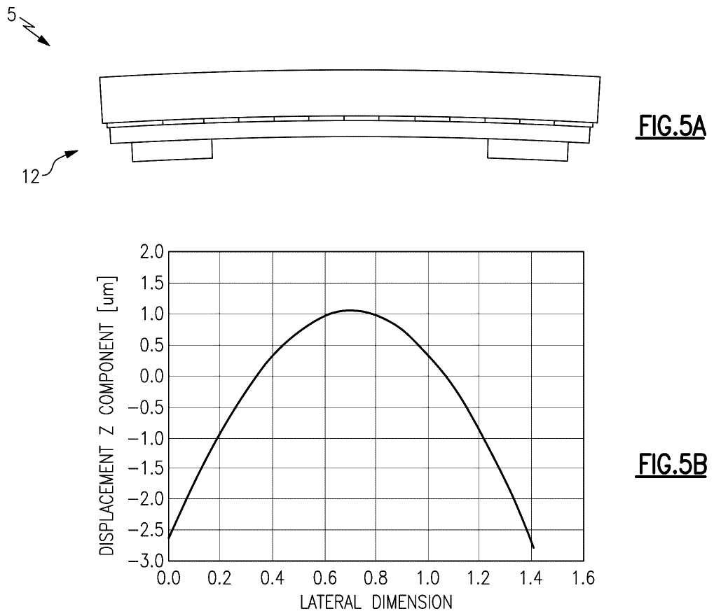

FIG. 5A is a simulated cross-sectional side view of a packaged multilayer piezoelectric substrate surface acoustic wave (MPS-SAW) device 5 after a temperature cycle. FIG. 5B is a graph showing a vertical displacement in the y-axis and a lateral location in the x-axis of the packaged MPS-SAW device 5 of FIG. 5A. The packaged MPS-SAW device 5 includes a silicon MPS-SAW device that includes a silicon support substrate and the packaging structure 12 shown in FIG. 2. The simulation results of FIGS. 5A and 5B indicate that the packaged MPS-SAW device 5 has significantly large (about 3.5 μm) vertical displacement after the temperature cycle. Also, the simulation results of FIGS. 5A and 5B indicate that the packaged MPS-SAW device 5 can cause the DC leakage.

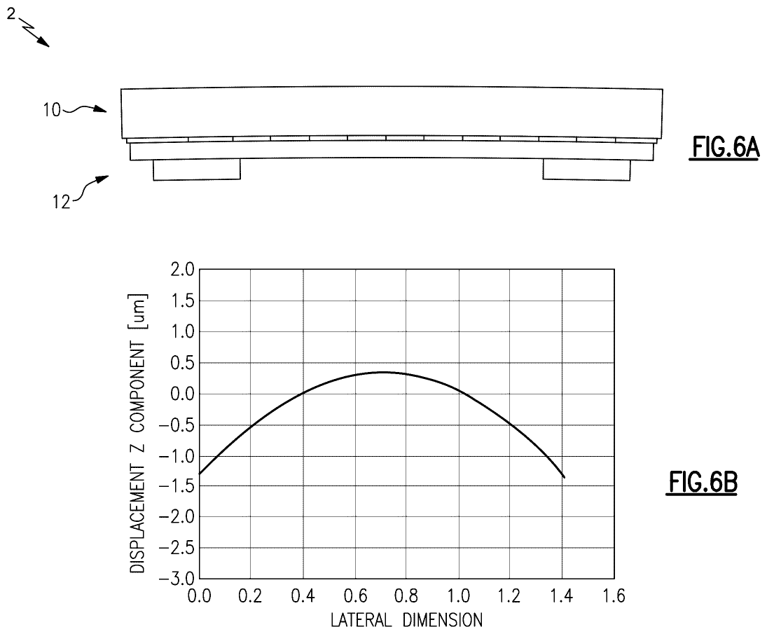

FIG. 6A is a simulated cross-sectional side view of a packaged multilayer piezoelectric substrate surface acoustic wave (MPS-SAW) device 2 of FIG. 2 after a temperature cycle. FIG. 6B is a graph showing a vertical displacement in the y-axis and a lateral location in the x-axis of the packaged MPS-SAW device 2 of FIG. 6A. The simulation results of FIGS. 6A and 6B indicate that the packaged MPS-SAW device 2 has sufficiently small (about 1.5 μm) vertical displacement after the temperature cycle. Also, the simulation results of FIGS. 6A and 6B indicate that the DC leakage was sufficiently blocked in the packaged MPS-SAW device 2.

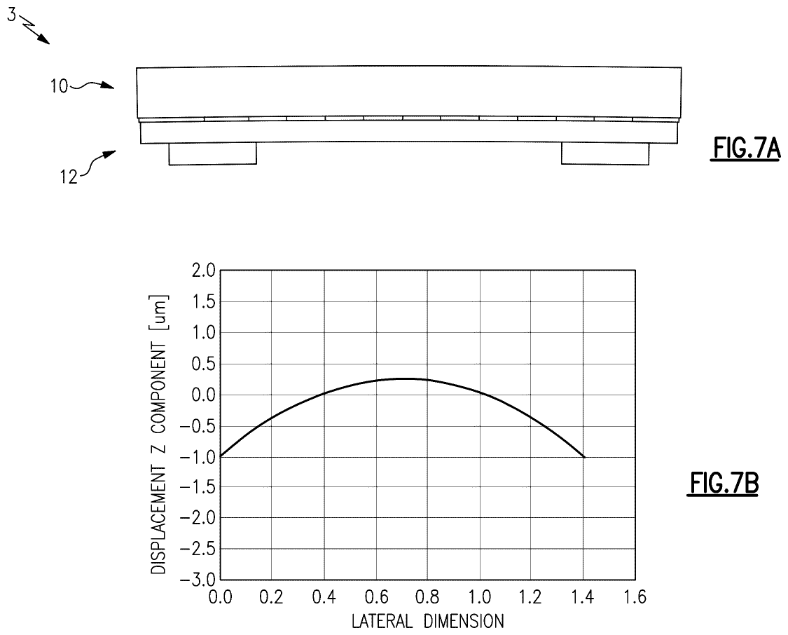

FIG. 7A is a simulated cross-sectional side view of a packaged multilayer piezoelectric substrate surface acoustic wave (MPS-SAW) device 3 of FIG. 3 after a temperature cycle. FIG. 7B is a graph showing a vertical displacement in the y-axis and a lateral location in the x-axis of the packaged MPS-SAW device 3 of FIG. 7A. The simulation results of FIGS. 7A and 7B indicate that the packaged MPS-SAW device 3 has sufficiently small (about 1.2 μm) vertical displacement after the temperature cycle. Also, the simulation results of FIGS. 7A and 7B indicate that the DC leakage was sufficiently blocked in the packaged MPS-SAW device 3.

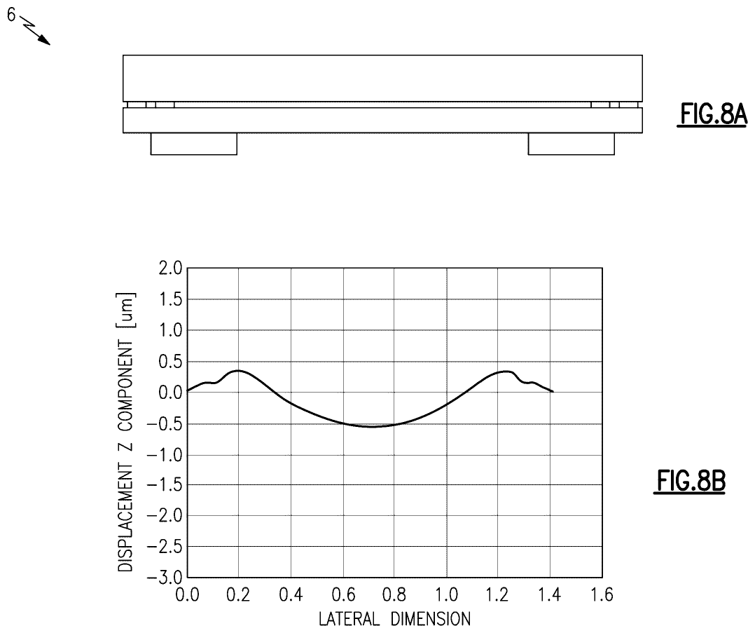

FIG. 8A is a simulated cross-sectional side view of a packaged multilayer piezoelectric substrate surface acoustic wave (MPS-SAW) device 6 after a temperature cycle. FIG. 8B is a graph showing a vertical displacement in the y-axis and a lateral location in the x-axis of the packaged MPS-SAW device 6 of FIG. 8A. The packaged MPS-SAW device 6 includes a silicon MPS-SAW device that includes a silicon support substrate and a silicon packaging structure. The simulation results of FIGS. 8A and 8B indicate that the packaged MPS-SAW device 6 has sufficiently small (about 1 μm) vertical displacement after the temperature cycle. However, the simulation results of FIGS. 8A and 8B indicate that the packaged MPS-SAW device 6 can cause the DC leakage.

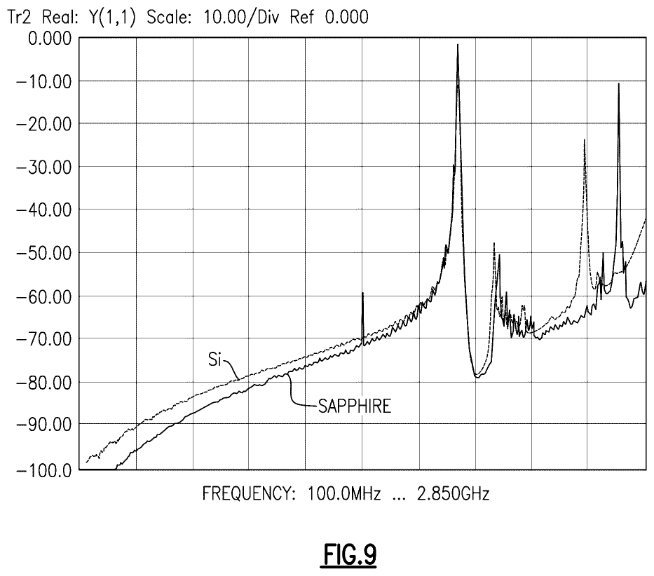

FIG. 9 is a graph showing comparison between the electrical performances of an MPS-SAW device with a silicon substrate and an MPS-SAW device with a sapphire substrate. FIG. 9 indicates that the MPS-SAW device with a silicon substrate and the MPS-SAW device with a sapphire substrate have generally similar electrical performance.

The packaged MPS-SAW devices that include a combination of a sapphire MPS and a polymer-based packaging structure disclosed herein can achieve a higher quality factor (Q), higher coupling coefficient K2, a more desirable temperature coefficient of frequency, and greater power handling capability than packaged TC-SAW devices. Also, the packaged MPS-SAW devices that include a combination of a sapphire MPS and a polymer-based packaging structure disclosed herein can achieve a more reliable (e.g., greater temperature-cycle reliability), and prevent or mitigate DC leakage through the support substrate.

The packaged MPS-SAW devices disclosed herein can be formed in any suitable manner. For example, a method of forming a packaged MPS-SAW device can include providing a multi-layer piezoelectric substrate device 10 that includes a support substrate 14 (e.g., a sapphire substrate), a piezoelectric layer 16 over the sapphire substrate, and an interdigital transducer electrode 18, 19 in electrical communication with the piezoelectric layer 16. The method can also include coupling a packaging structure 12 (e.g., a polymer-based packaging structure) to the multi-layer piezoelectric substrate device 10. The polymer-based packaging structure can include a conductive structure 22, a sidewall 12a, and a roof 12b. The roof 12b is at least partially positioned between the multi-layer piezoelectric substrate and a portion of the conductive structure 22. The interdigital transducer electrode 18, 19 can be positioned between the sapphire substrate and the roof 14b. In some embodiments, coupling the polymer-based packaging structure can include coupling the sidewall 12a to the multi-layer piezoelectric substrate.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more packaged MPS-SAW devices disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

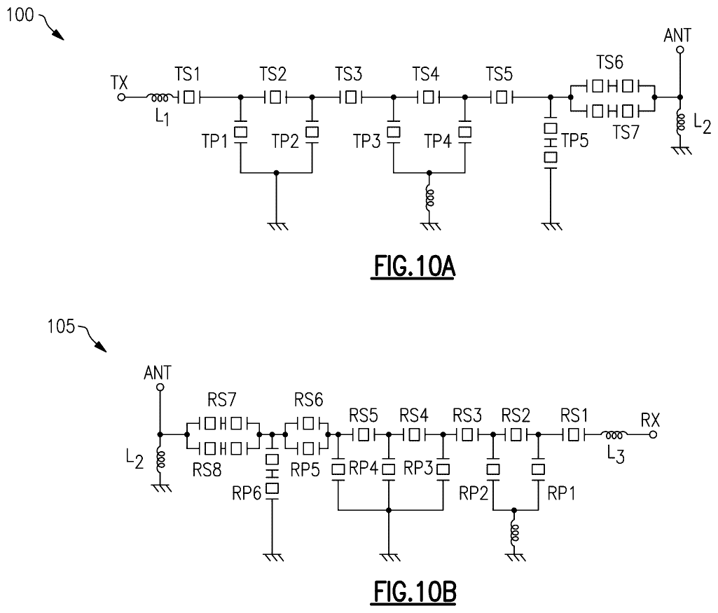

FIG. 10A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. Any suitable number of series SAW resonators and shunt SAW resonators can be included in a transmit filter 100.

FIG. 10B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 10A and 10B illustrate example ladder filter topologies, any suitable filter topology can include a packaged MPS-SAW device in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

FIG. 11 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 11 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 11. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

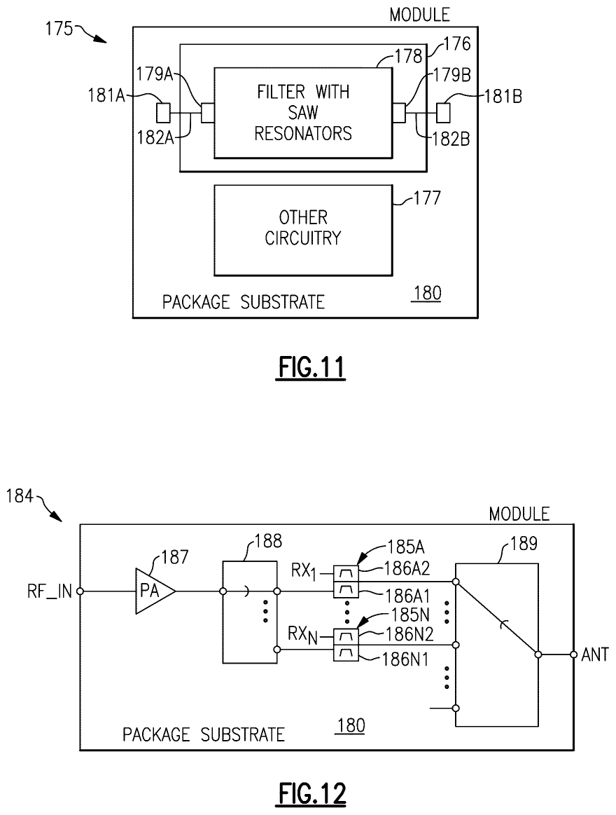

FIG. 12 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 12 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 13 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

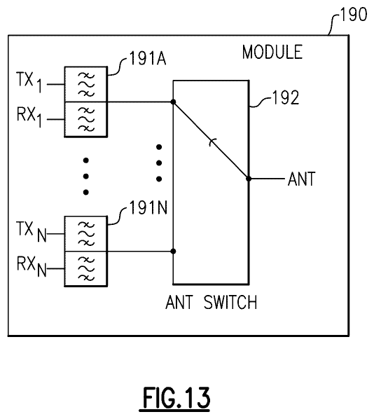

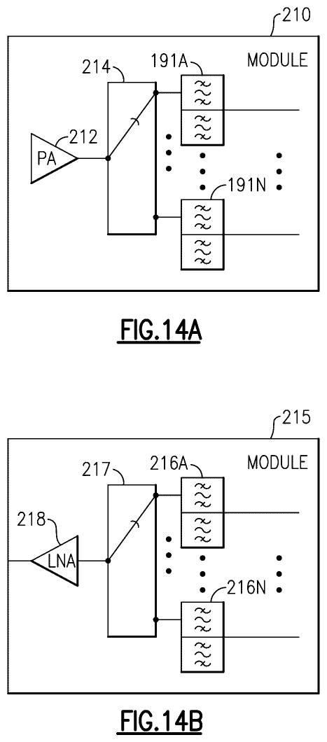

FIG. 14A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 14B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

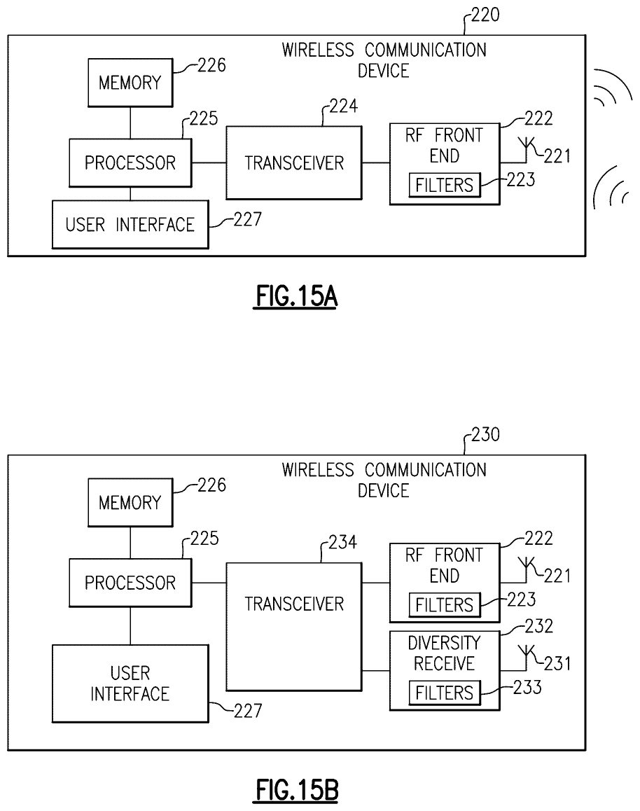

FIG. 15A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 15B is a schematic diagram of a wireless communication device 230 that includes filters 223 in a radio frequency front end 222 and a second filter 233 in a diversity receive module 232. The wireless communication device 230 is like the wireless communication device 220 of FIG. 15A, except that the wireless communication device 230 also includes diversity receive features. As illustrated in FIG. 15B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHZ. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A packaged multi-layer piezoelectric substrate surface acoustic wave device comprising:
a multi-layer piezoelectric substrate including a piezoelectric layer and a sapphire substrate;
an interdigital transducer electrode in electrical communication with the piezoelectric layer; and
a polymer-based packaging structure including a conductive structure, a sidewall, and a roof, the roof at least partially positioned between the multi-layer piezoelectric substrate and a portion of the conductive structure, the sidewall coupled to the multi-layer piezoelectric substrate, and the interdigital transducer electrode positioned between the sapphire substrate and the roof.

2. The packaged surface acoustic wave device of claim 1 wherein the roof includes a first roof portion between the multi-layer piezoelectric substrate and the portion of the conductive structure, and a second roof portion.

3. The packaged surface acoustic wave device of claim 2 wherein the second roof portion includes a silica-filled polymer.

4. The packaged surface acoustic wave device of claim 2 wherein the portion of the conductive structure is positioned between the first and second roof portions.

5. The packaged surface acoustic wave device of claim 1 wherein the multi-layer piezoelectric substrate further includes a silicon oxide layer between the piezoelectric layer and the sapphire substrate.

6. The packaged surface acoustic wave device of claim 5 wherein the silicon oxide layer is in direct contact with the sapphire substrate.

7. The packaged surface acoustic wave device of claim 1 wherein the polymer-based packaging structure further includes a terminal, and the conductive structure connects the terminal and the multi-layer piezoelectric substrate.

8. The packaged surface acoustic wave device of claim 1 wherein the conductive structure includes a metal trace or a patterned metal plate.

9. The packaged surface acoustic wave device of claim 1 wherein the roof, the sidewall and the multi-layer piezoelectric substrate together define a cavity in which the interdigital transducer electrode is positioned.

10. The packaged surface acoustic wave device of claim 1 wherein the polymer-based packaging structure has a coefficient of thermal expansion greater than 0 ppm/° C. and equal to or less than 35 ppm/° C.

11. A method of forming a packaged multi-layer piezoelectric substrate surface acoustic wave device, the method comprising:
providing a multi-layer piezoelectric substrate device including a sapphire substrate, a piezoelectric layer over the sapphire substrate, and an interdigital transducer electrode in electrical communication with the piezoelectric layer; and
coupling a polymer-based packaging structure to the multi-layer piezoelectric substrate device, the polymer-based packaging structure including a conductive structure, a sidewall, and a roof, the roof at least partially positioned between the multi-layer piezoelectric substrate and a portion of the conductive structure, and the interdigital transducer electrode positioned between the sapphire substrate and the roof.

12. The method of claim 11 wherein coupling the polymer-based packaging structure includes coupling the sidewall to the multi-layer piezoelectric substrate.

13. The method of claim 11 wherein the roof includes a first roof portion between the multi-layer piezoelectric substrate and the portion of the conductive structure, and a second roof portion including a silica-filled polymer.

14. The method of claim 13 wherein the portion of the conductive structure is positioned between the first and second roof portions.

15. The method of claim 11 wherein multi-layer piezoelectric substrate further includes a silicon oxide layer between the piezoelectric layer and the sapphire substrate.

16. The method of claim 11 wherein the polymer-based packaging structure further includes a terminal, and the conductive structure connects the terminal and the multi-layer piezoelectric substrate.

17. The method of claim 11 wherein the conductive structure includes a metal trace or a patterned metal plate.

18. The method of claim 11 wherein the roof, the sidewall and the multi-layer piezoelectric substrate together define a cavity in which the interdigital transducer electrode is positioned.

19. The method of claim 11 wherein the polymer-based packaging structure has a coefficient of thermal expansion greater than 0 ppm/° C. and equal to or less than 35 ppm/° C.

20. A packaged multi-layer piezoelectric substrate surface acoustic wave device comprising:
a multi-layer piezoelectric substrate surface acoustic wave device including a multi-layer piezoelectric substrate having a piezoelectric layer and a sapphire substrate, and an interdigital transducer electrode in electrical communication with the piezoelectric layer; and
a polymer-based packaging structure including a conductive structure, a sidewall, and a roof, the roof having a first roof portion and a second roof portion, the conductive structure positioned between the first roof portion and the second roof portion, and the interdigital transducer electrode positioned between the sapphire substrate and the roof.
